(19) United States
(12) Patent Application Publication
(10) Pub. No.: US 2025/0113644 A1
(43) Pub. Date: Apr. 3, 2025

(54) UV PHOTOTRANSISTER FOR PURE UV LIGHT DETECTION AND ITS MANUFACTURING METHOD

(71) Applicant: University-Industry Cooperation Group of Kyung Hee University, Yongin-Si (KR)

(72) Inventors: Seong Jun Kang, Seoul (KR); Min Gye Kim, Gunpo-si (KR)

(73) Assignee: University-Industry Cooperation Group of Kyung Hee University, Yongin-Si (KR)

(21) Appl. No.: 18/898,983

(22) Filed: Sep. 27, 2024

(30) Foreign Application Priority Data
Sep. 27, 2023 (KR) 10-2023-0130812

(51) Int. Cl. H10F 71/00; H10F 30/28

(52) U.S. Cl. CPC H10F 71/134; H10F 30/28

(57) ABSTRACT

A method of manufacturing a UV phototransistor and a UV transistor manufactured according to the same are disclosed herein. The method includes mixing a solvent comprising 2-methoxyethanol, 2-ethoxyethanol, and ethylene glycol with an oxide semiconductor to prepare a photoactive solution; applying the prepared photoactive solution onto a substrate to form a photoactive layer, and forming electrodes spaced apart on the photoactive layer.

### CROSS-REFERENCE TO RELATED APPLICATION

This application claims the benefit under 35 U.S.C. § 119 of Korean Patent Application No. 10-2023-0130812 filed on Sep. 27, 2023, in the Korean Intellectual Property Office, the entire disclosure of which is incorporated herein by reference for all purposes.

### BACKGROUND

### 1. Field

The present disclosure relates to a ultraviolet (UV) phototransistor and a method of manufacturing the same, and in particular, to a UV phototransistor with suppressed responsivity in the visible light region and enhanced responsivity in the UV light region, as well as a method of manufacturing the same.

### 2. Description of Related Art

The ultraviolet (UV) sensor is a sensor that detects light in the ultraviolet region. Research on ultraviolet detection sensors, which detect ultraviolet light that causes diseases such as skin cancer and cataracts, is being actively conducted. One of the critical characteristics of a UV sensor is the ability to detect light in the pure ultraviolet range without interference from the visible light region. However, conventional optical sensors have struggled to absorb only light in the pure UV wavelength range due to effects caused by defects in thin films, which lead to the absorption of light across various wavelengths.

To address such issues, wide-bandgap oxide semiconductors, such as ZnO (Zinc Oxide), NiO (Nickel Oxide), In₂O₃ (Indium Oxide), and Indium-Gallium-Zinc-Oxide (IGZO), are being utilized as channel layers in phototransistors. Among these, IGZO is a representative oxide semiconductor with high charge mobility and stability. Its charge mobility is determined by oxygen vacancies generated in the sub-lattice. However, a large number of trap states, including shallow traps and deep traps within the bandgap of IGZO, exist at these energy levels. These trap states can detect visible light, which makes it challenging to exclusively detect pure UV light.

A representative method to reduce the responsiveness to visible light is to decrease the amount of oxygen vacancies within the bandgap. However, since the mobility is determined by electrons generated during the formation of oxygen vacancies, reducing the number of oxygen vacancies results in a deterioration of the electrical properties.

The present invention has been devised to solve the aforementioned problems. A primary objective of the invention is to provide a UV phototransistor and its manufacturing method, which can reduce the formation of oxygen vacancies in oxide semiconductors while simultaneously suppressing the deterioration of electrical properties.

Furthermore, a secondary objective of the present invention is to provide a UV phototransistor that exhibits increased responsiveness in the UV region.

### SUMMARY

As a means for achieving the aforementioned object, the present disclosure suggests a method of manufacturing an ultraviolet (UV) phototransistor comprising mixing a solvent comprising 2-methoxyethanol, 2-ethoxyethanol, and ethylene glycol with an oxide semiconductor to prepare a photoactive solution; applying the prepared photoactive solution onto a substrate to form a photoactive layer; and forming electrodes spaced apart on the photoactive layer.

The oxide semiconductor may be one or more materials selected from a group of ZnO, In₂O₃ and Indium-Gallium-Zinc-Oxide (IGZO).

The solvent may comprise 2-methoxyethanol, 2-ethoxyethanol, and ethylene glycol in a volume ratio of 8:1:1 to 8:1:8.

The manufacturing method may further comprise performing UV/ozone (UVO) treatment on the formed photoactive layer.

The UVO treatment may be performed for 1 to 10 minutes.

In addition, as a means for achieving the aforementioned object, the present disclosure suggests a UV phototransistor comprising a substrate; a photoactive layer formed by applying a photoactive solution onto the substrate, the photoactive solution prepared by mixing a solvent comprising 2-methoxyethanol, 2-ethoxyethanol, and ethylene glycol with an oxide semiconductor; and electrodes formed spaced apart on the photoactive layer.

A thickness of the photoactive layer may be 2 to 30 nm.

In the UV phototransistor, photocurrent may be generated through desorption of hydroxyl groups present on a surface of the photoactive layer.

The hydroxyl groups present on the surface of the photoactive layer may be included at a ratio of 30 to 60% with respect to the surface of the photoactive layer. In the UV phototransistor, light absorption in visible region may be reduced.

### BRIEF DESCRIPTION OF THE DRAWINGS

FIG. 1 is a flowchart illustrating a method of manufacturing a UV phototransistor according to the present invention.

FIG. 2 is a schematic diagram illustrating a manufacturing process of a UV phototransistor according to an example of the present invention.

FIG. 3 is a schematic diagram illustrating a UV phototransistor according to the present invention.

FIG. 4 shows the XRD spectrum of a photoactive layer manufactured according to an example of the present invention.

FIG. 5 shows the XPS spectrum for N 1s of a photoactive layer manufactured according to an example of the present invention.

FIG. 6 shows the XPS spectrum for C 1s of a photoactive layer manufactured according to an example of the present invention.

FIG. 7 is a graph showing the distribution ratios of hydroxyl groups and oxygen vacancies in a photoactive layer manufactured according to an example of the present invention. Referring

FIG. 8 shows the XPS spectrum of O 1s for a photoactive layer manufactured according to an example of the present invention.

FIG. 9 illustrates a bandgap diagram of a photoactive layer manufactured according to an example of the present invention.

FIG. 10 illustrates a bandgap diagram of a photoactive layer manufactured according to an example of the present invention.

FIG. 11 is a graph showing the photoresponsivity of a photoreactive layer with respect to wavelength, manufactured according to an example of the present invention.

FIG. 12 is a graph showing the photosensitivity of a UV phototransistor with respect to wavelength, manufactured according to an example of the present invention.

FIG. 13 is a graph illustrating the current variation of a UV phototransistor manufactured according to an example of the present invention, depending on the application of light.

FIG. 14 is a graph illustrating the variation in current of the UV phototransistor manufactured according to an example of the present invention, depending on the application of light.

### DETAILED DESCRIPTION

The present invention is subject to various modifications and may have numerous embodiments. Specific embodiments are illustrated in the drawings and described in detail herein. However, this is not intended to limit the invention to these particular forms of implementation. It should be understood that all modifications, equivalents, and substitutions falling within the spirit and scope of the invention are included.

Throughout this specification, when a certain part is described as “including” a specific component, it does not exclude other components unless explicitly stated otherwise, and it may further include additional components.

Terms such as “approximately” and “substantially,” as used herein, are employed to describe numerical values that allow for manufacturing and material tolerances inherent to the stated meaning. These terms are also used to prevent unscrupulous infringement by exact or absolute numerical disclosures from being unjustly exploited. Furthermore, the phrases “step of” or “step for” as used throughout this specification do not imply a step solely for a specific purpose.

A person skilled in the art to which the present invention pertains will be able to apply the gist of the invention in various ways. Therefore, the scope of the present invention is not limited to the embodiments described below. The scope of the present invention extends to parts that are obvious for a person skilled in the art of the invention's technical field to substitute or modify easily using conventional technology, based on the matters described in the claims.

Hereinafter, the invention will be described in more detail with reference to the accompanying drawings, as necessary.

### <Method of Manufacturing UV Phototransistor>

The present invention discloses a method for manufacturing a UV phototransistor as a means to achieve the aforementioned objectives.

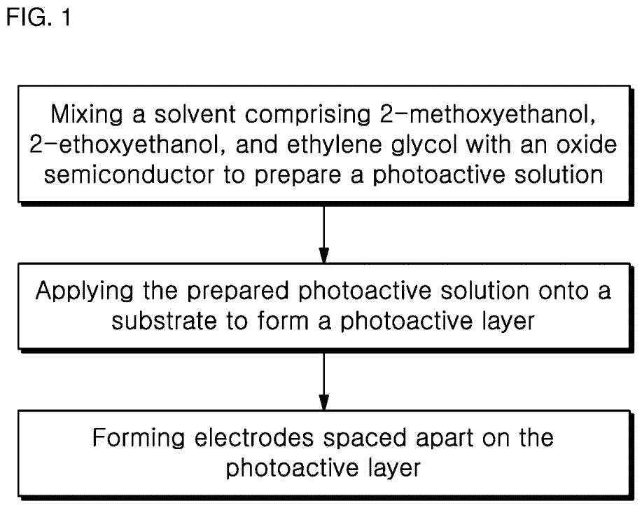

FIG. 1 is a flowchart illustrating a method of manufacturing a UV phototransistor according to the present invention. Referring to FIG. 1, a manufacturing method of the UV phototransistor according to the present invention includes the steps of: preparing a photoactive solution by mixing a solvent comprising 2-methoxyethanol, 2-ethoxyethanol, and ethylene glycol with an oxide semiconductor; forming a photoactive layer by applying the prepared photoactive solution onto a substrate; and forming electrodes spaced apart on the photoactive layer.

The UV phototransistor of the present invention includes 2-ethoxyethanol and ethylene glycol in the 2-methoxyethanol, which is typically used as a solvent in the preparation of the photoactive solution, thereby reducing various defect states present in the bandgap and providing detachable hydroxyl groups on the surface of the photoactive layer. This aims to suppress light reactivity in the visible light region while enhancing light reactivity in the UV light region.

The substrate may be made of materials such as glass, Si/SiO₂, PET, PDMS, Polyimide (PI), but is not limited thereto.

The oxide semiconductor may be any one or more substances selected from a group comprising ZnO, In₂O₃, and IGZO, but is not limited thereto.

The photoactive solution may be prepared by first preparing an oxide semiconductor stock solution using 2-methoxyethanol as the solvent, and then adding 2-ethoxyethanol and ethylene glycol to the prepared oxide semiconductor stock solution.

The 2-ethoxyethanol contains a terminal alkyl group, which induces strained bonding caused by the weak crystallinity of the oxide semiconductor, thereby adsorbing OH from the surrounding environment onto the surface of the photoactive layer, while simultaneously ensuring the stability of the oxide semiconductor.

As for ethylene glycol, its high polarity makes it easy to detach metal cations and anions in the solution, allowing control of the quantity of NO⁻-related defect states caused by the oxide semiconductor precursor.

The 2-methoxyethanol, 2-ethoxyethanol, and ethylene glycol may be included in a volume ratio of 8:1:1 to 8:1:8. If the volume ratio of 2-methoxyethanol, 2-ethoxyethanol, and ethylene glycol deviates from this range, issues arise such as reduced adsorption of OH-on the surface of the photoactive layer and failure to control NO-related defects, leading to a deterioration in the performance of the UV sensor.

The prepared photoactive solution may be applied onto the substrate through a solution process. The solution process may include spin coating, dip coating, inkjet printing, offset printing, reverse offset printing, gravure printing, roll printing, etc., but is not limited thereto. Any commonly used solution process may be employed.

The photoactive solution applied onto the substrate may form a photoactive layer through annealing. There is no specific limitation on the annealing temperature, as long as it does not induce degradation of the photoactive performance of the photoactive layer.

The material used for the electrodes is not particularly limited, and known materials may be used. The formation method may also be performed according to known methods. In one embodiment of the present invention, the electrode may be made of Al and formed by thermal evaporation.

The method of manufacturing a UV phototransistor may further include a step of performing UV/ozone (UVO) treatment on the formed photoactive layer. The timing of the UVO treatment is not particularly limited, and it may be performed either before the electrodes are formed or after the electrodes are formed. By performing the UVO treatment in the method of the present invention, the amount of OH⁻ that may be detached by UV light on the photoactive layer may be increased, and the amount of trap states may be reduced, thereby improving the photoresponsivity and reaction selectivity to UV light.

The UVO treatment may be performed for 1 to 10 minutes.

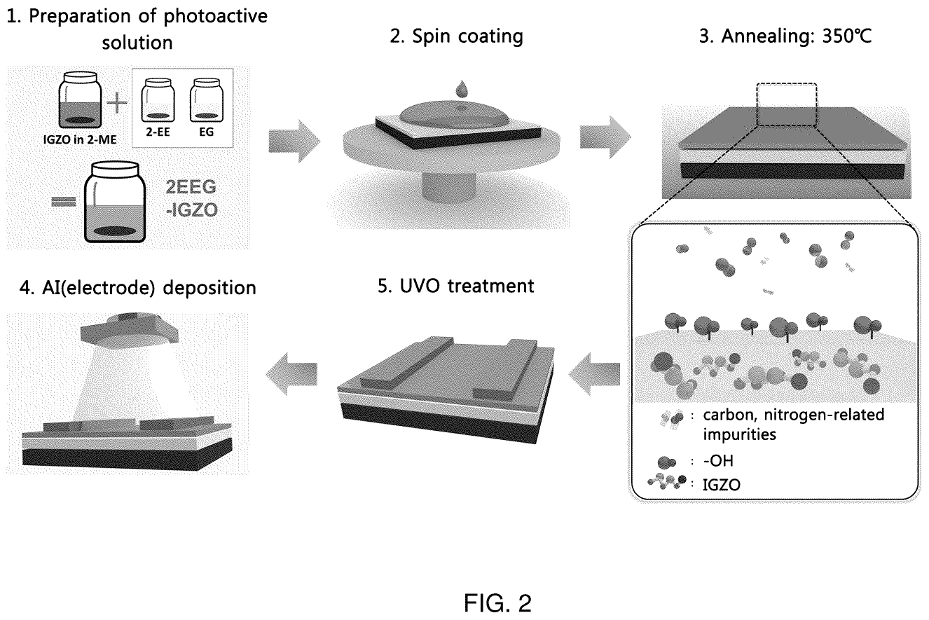

FIG. 2 is a schematic diagram illustrating a manufacturing process of a UV phototransistor according to an example of the present invention. Referring to FIG. 2, the method of manufacturing a UV phototransistor according to the present invention includes, for example, adding 2-ethoxyethanol (2-EE) and ethylene glycol (EG) to an oxide semiconductor stock solution (IGZO in 2-ME (2-methoxyethanol)) to prepare a photoactive solution (2EEG-IGZO) and applying the prepared photoactive solution onto a substrate via spin coating. The coated photoactive solution is annealed at 350° C. to form a photoactive layer, after which a metal (Al) electrode may be deposited on the formed photoactive layer. Subsequently, UVO treatment may also be performed.

### <UV Phototransistor>

Furthermore, the present invention discloses, as a means to achieve the aforementioned objectives, a UV phototransistor comprising: a substrate; a photoactive layer formed by applying a photoactive solution, prepared by mixing a solvent comprising 2-methoxyethanol, 2-ethoxyethanol, and ethylene glycol with an oxide semiconductor, onto the substrate; and electrodes formed spaced apart on the photoactive layer.

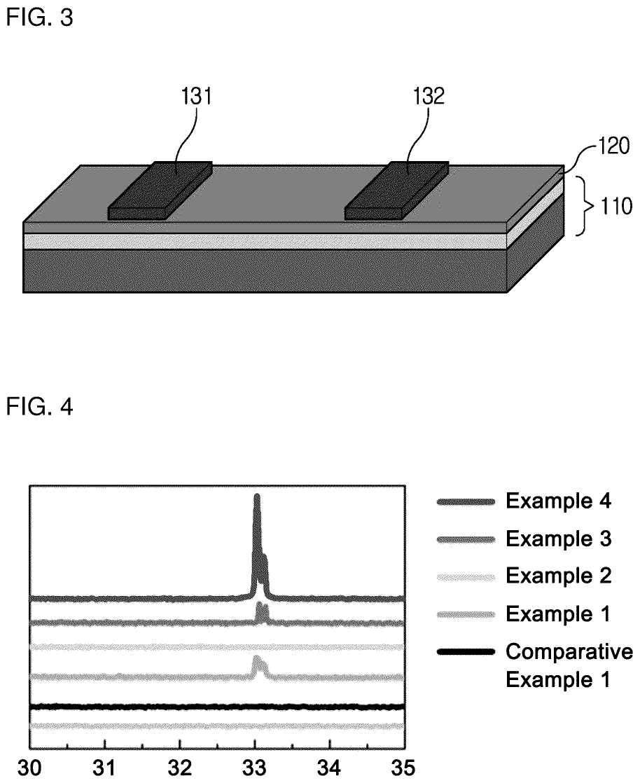

FIG. 3 is a schematic diagram illustrating a UV phototransistor according to the present invention. Referring to FIG. 3, it can be confirmed that the UV phototransistor according to the present invention includes a substrate 110; a photoactive layer 120 formed on the substrate 110; and electrodes 131, 132 spaced apart and formed on the photoactive layer 120. The electrodes 131, 132 may serve as a source electrode and a drain electrode, respectively.

Here, the thickness of the photoactive layer is preferably in the range of 2 to 30 nm, and more preferably in the range of 3 to 10 nm. If the thickness falls outside the range of 2 to 30 nm, there may arise an issue of reduced photoactive properties in the UV phototransistor according to the present invention.

Here, in the UV phototransistor, photocurrent may be formed through the desorption of hydroxyl groups present on the surface of the photoactive layer. As described above, the UV phototransistor according to the present invention may reduce various defect states present within the bandgap and, through the desorption of hydroxyl groups on the surface of the photoactive layer, decrease light responsiveness in the visible light region while increasing light responsiveness in the UV light region.

Here, it is preferable that the hydroxyl groups present on the surface of the photoactive layer are included at a ratio of 30% to 60% with respect to the surface of the photoactive layer. If the hydroxyl group content is less than 30%, light responsiveness through hydroxyl group desorption may be reduced, leading to a decrease in performance as a photosensor.

Here, the UV phototransistor may exhibit reduced light responsiveness in the visible light region. More specific details regarding the light responsiveness of the UV phototransistor according to the present invention will be described in greater detail in the {Examples and Evaluation} section below.

The claims of this specification will now be described in further detail with reference to the attached drawings and examples. However, the drawings and examples presented in this specification are merely illustrative and may be modified in various ways by those skilled in the art to take on different forms. Therefore, the technical matters disclosed herein should not be construed as being limited to the specific embodiments disclosed but should be understood to encompass all equivalents and substitutes within the spirit and scope of the present invention. Additionally, the attached drawings are provided to help those skilled in the art better understand the invention and may be exaggerated or reduced in scale compared to the actual dimensions.

### Examples and Evaluation

### EXAMPLES

### Example 1

### 1. Preparation of the Photoactive Solution

Using 2-methoxyethanol as the solvent, 0.1 M In₂O₃, 0.1 M Ga₂O₃, and 0.1 M ZnO were mixed in a volume ratio of 5:1:2 to prepare an IGZO stock solution. The prepared IGZO stock solution was then mixed with 2-ethoxyethanol and ethylene glycol in a volume ratio of 8:1:1 to prepare the photoactive solution.

### 2. Manufacturing of the UV Phototransistor

Si/SiO₂ was used as the substrate. The prepared photoactive solution was spin-coated onto the substrate, followed by annealing at 350° C. to form the photoactive layer. Aluminum (Al) electrodes, serving as the source and drain electrodes, were deposited on the formed photoactive layer to manufacture the final UV phototransistor (hereinafter referred to as “Example 1”).

### Example 2

A photoactive layer and UV phototransistor were produced in the same manner as in Example 1, except that the IGZO stock solution, 2-ethoxyethanol, and ethylene glycol were mixed in a volume ratio of 8:1:2 (hereinafter referred to as “Example 2”).

### Example 3

A photoactive layer and UV phototransistor were produced in the same manner as in Example 1, except that the IGZO stock solution, 2-ethoxyethanol, and ethylene glycol were mixed in a volume ratio of 8:1:4 (hereinafter referred to as “Example 3”).

### Example 4

A photoactive layer and UV phototransistor were produced in the same manner as in Example 1, except that the IGZO stock solution, 2-ethoxyethanol, and ethylene glycol were mixed in a volume ratio of 8:1:8 (hereinafter referred to as “Example 4”).

### Comparative Example 1

Using 2-methoxyethanol as the solvent, 0.1 M In₂O₃, 0.1 M Ga₂O₃, and 0.1 M ZnO were mixed in a volume ratio of 5:1:2 to prepare an IGZO stock solution. The prepared IGZO stock solution was spin-coated onto a substrate (Si/SiO₂) and then annealed (350° C.) to form the photoactive layer.

Aluminum (Al) electrodes, serving as the source and drain electrodes, were deposited on the formed photoactive layer, and the final UV phototransistor was manufactured (hereinafter referred to as “Comparative Example 1”).

Examples 1 to 4 and Comparative Example 1 may refer to the photoactive layer, and may also refer to the UV phototransistor manufactured, including the photoactive layer.

### Example 5

After depositing the Al electrode in Example 1, an additional UVO treatment was performed for 1 minute to manufacture the UV phototransistor (hereinafter referred to as “Example 5”).

### Example 6

After depositing the Al electrode in Example 1, an additional UVO treatment was performed for 2 minutes to manufacture the UV phototransistor (hereinafter referred to as “Example 6”).

### Example 7

After depositing the Al electrode in Example 1, an additional UVO treatment was performed for 3 minutes to manufacture the UV phototransistor (hereinafter referred to as “Example 7”).

### <Evaluation>

### 1. XRD and XPS Evaluation

FIG. 4 shows the XRD spectrum of a photoactive layer manufactured according to an example of the present invention. Referring to FIG. 4, it can be confirmed that Examples 1 to 4 show a peak around a 20 value of 33°. This is because, during the manufacture of the photoactive layer in the present invention, 2-ethoxyethanol was included as the solvent, which increases the crystallinity of the photoactive layer. This crystallinity induces strained bonding, leading to this result. The photoactive layer of the present invention, which has induced strained bonding, may adsorb hydroxyl groups from the surrounding environment, thereby improving the stability of the photoactive layer thin film.

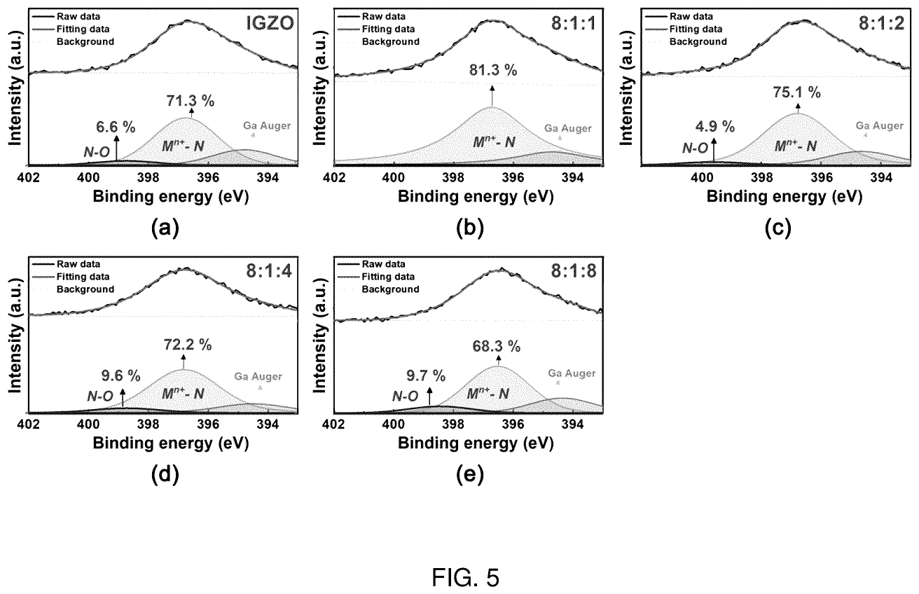

FIG. 5 shows the XPS spectrum for N 1s of a photoactive layer manufactured according to an example of the present invention. More specifically, (a) of FIG. 5 is the XPS spectrum for N 1s of the photoactive layer manufactured according to Comparative Example 1; (b) of FIG. 5 is the XPS spectrum for N 1s of the photoactive layer manufactured according to Example 1; (c) of FIG. 5 is the XPS spectrum for N 1s of the photoactive layer manufactured according to Example 2; (d) of FIG. 5 is the XPS spectrum for N 1s of the photoactive layer manufactured according to Example 3; and € of FIG. 5 is the XPS spectrum for N 1s of the photoactive layer manufactured according to Example 4. The N 1s peaks shown in FIG. 5 were deconvoluted to calculate the ratios corresponding to the peaks associated with Mⁿ⁺-N and N—O, respectively. The value corresponding to the N—O ratio was divided by a value corresponding to the Mⁿ⁺-N ratio to calculate the ratio of N—O bonds to Mⁿ⁺-N bonds. The specific values for the Mⁿ⁺-N ratio, the unresolved N—O ratio, and the ratio of N—O bonds to Mⁿ⁺-N bonds are presented in Table 1 below.

TABLE 1

| | Mⁿ⁺—N | | Ratio of |
|---|---|---|---|
| | (M: In, | | N—O Bonds to |
| Classification | Ga, Zn) | N—O | Mⁿ⁺—N Bonds |
| Comparative | 71.3 | 6.6 | 9.26% |
| Example 1 | | | |
| Example 1 | 81.3 | 0 | 0% |
| Example 2 | 75.1 | 4.9 | 6.52% |
| Example 3 | 72.2 | 9.6 | 13.3% |
| Example 4 | 68.3 | 9.7 | 14.2% |

Referring to FIG. 5 and Table 1, in the case of the photoactive layers manufactured according to Examples 1 and 2, the ratio of unresolved N—O to Mⁿ⁺-N area decreased to 0% and 6.52%, respectively, compared to the photoactive layer manufactured according to Comparative Example 1 (9.26%), due to successful precursor decomposition. These results indicate that the photoactive layer according to the present invention enables optimization of nitrogen-related bonding.

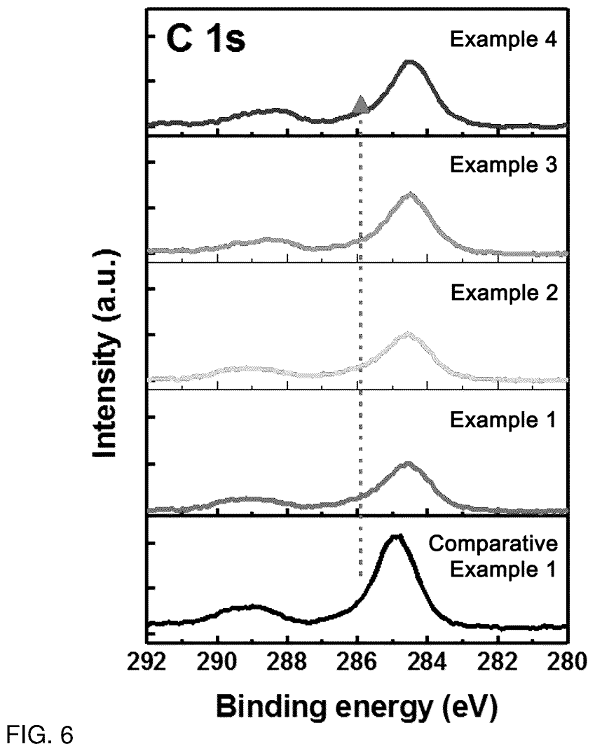

FIG. 6 shows the XPS spectrum for C 1s of a photoactive layer manufactured according to an example of the present invention. Referring to FIG. 6, the ratio of C 1s in the XPS spectrum indicates the presence of deep trap states. It can also be confirmed that this ratio decreased to 14.6% and 14.3% in Examples 1 and 2, respectively, compared to Comparative Example 1 (19.9%). The above results signify a successful reduction of trap states within the IGZO bandgap, further suggesting that the generation of photocurrent in the visible light region due to defects may be reduced.

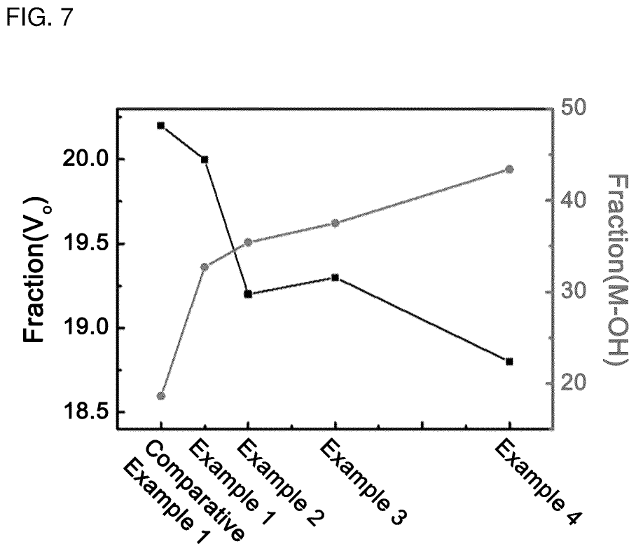

FIG. 7 is a graph showing the distribution ratios of hydroxyl groups and oxygen vacancies in a photoactive layer manufactured according to an example of the present invention. Referring to FIG. 7, the ratios of 02, —CO₃, and —OH adsorbed from the surrounding environment are observed to be 18.6% in Comparative Example 1, whereas they significantly increased to 32.7% in Example 1, 35.4% in Example 2, 37.5% in Example 3, and 43.4% in Example 4. As confirmed in FIG. 6, the decrease in the C 1s peak ratio with the addition of 2-ethoxyethanol and ethylene glycol as solvents suggests that the increase in the O 1s peak observed in FIG. 7 is not due to contamination from the surrounding environment. Instead, it can be inferred that this increase results from the adsorption of O₂⁻ or OH⁻ on the surface of the photoactive layer. Thus, the UV phototransistor of the present invention is expected to achieve enhanced performance as a pure UV sensor through the significant desorption of OH⁻.

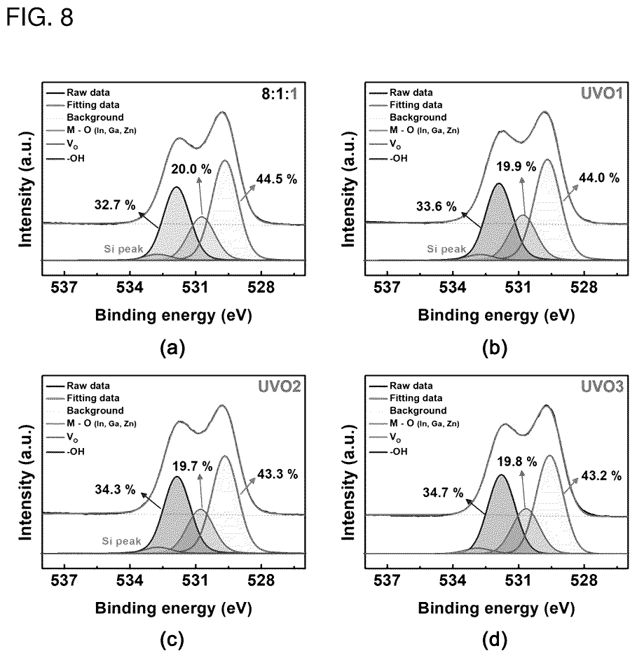

FIG. 8 shows the XPS spectrum of O 1s for a photoactive layer manufactured according to an example of the present invention. Specifically, (a) of FIG. 8 shows the XPS spectrum of O 1s for the photoactive layer manufactured according to Example 1; (b) of FIG. 8 shows the XPS spectrum of O 1s for the photoactive layer manufactured according to Example 5; (c) of FIG. 8 shows the XPS spectrum of O 1s for the photoactive layer manufactured according to Example 6; and (d) of FIG. 8 shows the XPS spectrum of O 1s for the photoactive layer manufactured according to Example 7. Referring to FIG. 8, it is confirmed that the photoactive layers manufactured according to Examples 6 and 7 exhibit an increased peak value for the —OH bond compared to the photoactive layer manufactured according to Example 1. This indicates that the photoactive layer of the present invention enhances the amount of OH⁻ that can be desorbed under UV light as the UVO treatment is further performed. Consequently, this is expected to reduce the number of trap states in the bandgap.

### 2. Energy Level Evaluation

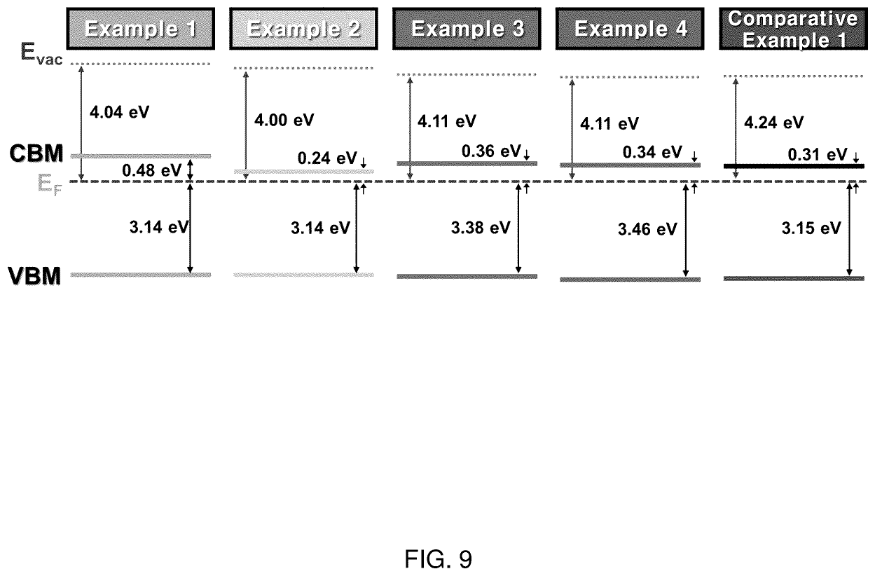

FIG. 9 illustrates a bandgap diagram of a photoactive layer manufactured according to an example of the present invention. Referring to FIG. 9, the difference between the valence band maximum (VBM) and the Fermi level (EF) is observed to be 3.15 eV for Comparative Example 1, whereas it is 3.38 eV for Example 3 and 3.46 eV for Example 4. Considering that the energy level of oxygen vacancies is positioned 0.8 to 1 eV above the VBM, the relatively distant position of the oxygen vacancy level suggests that it effectively suppresses reactivity in the long-wavelength visible light region.

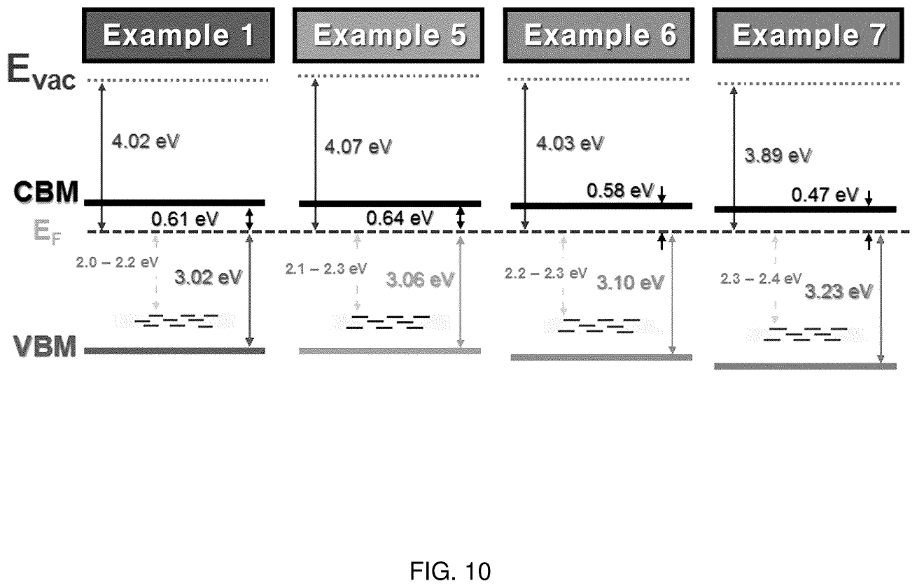

FIG. 10 illustrates a bandgap diagram of a photoactive layer manufactured according to an example of the present invention. Referring to FIG. 10, it can be seen that as the UVO treatment time increases, the VBM value shifts to a lower value. As explained in FIG. 9, considering that the energy level of oxygen vacancies is located 0.8 to 1 eV above the VBM, the relatively distant position of the oxygen vacancy level suggests that it successfully suppresses reactivity in the long-wavelength visible light region.

### 3. Photoresponsivity Evaluation

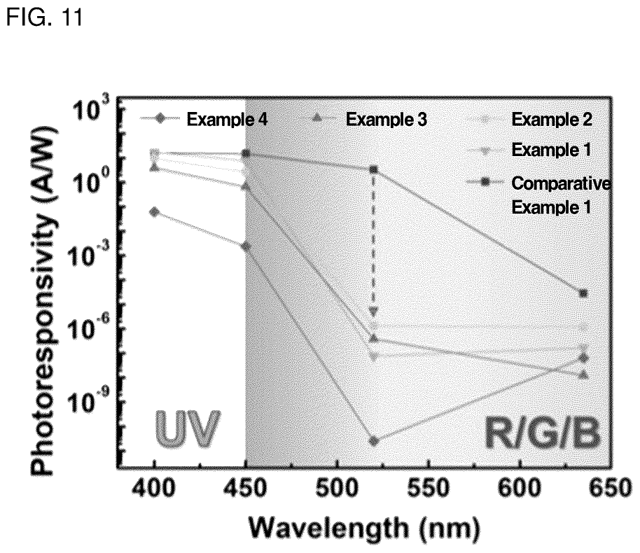

FIG. 11 is a graph showing photoresponsivity according to wavelengths of a photoreactive layer manufactured according to an example of the present invention. Referring to FIG. 11, it can be seen that the photoreactive layers manufactured according to Examples 1 to 4 exhibit reduced photoresponsivity in the visible light region around 525 nm compared to Comparative Example 1. In particular, Examples 1 to 3 maintain the same level of photoresponsivity in the ultraviolet region as Comparative Example 1, while showing a decrease in photoresponsivity in the visible light region. This result suggests that by adding 2-ethoxyethanol and ethylene glycol during the manufacture of the photoreactive layer of the present invention, the reactivity in the visible light region is successfully suppressed.

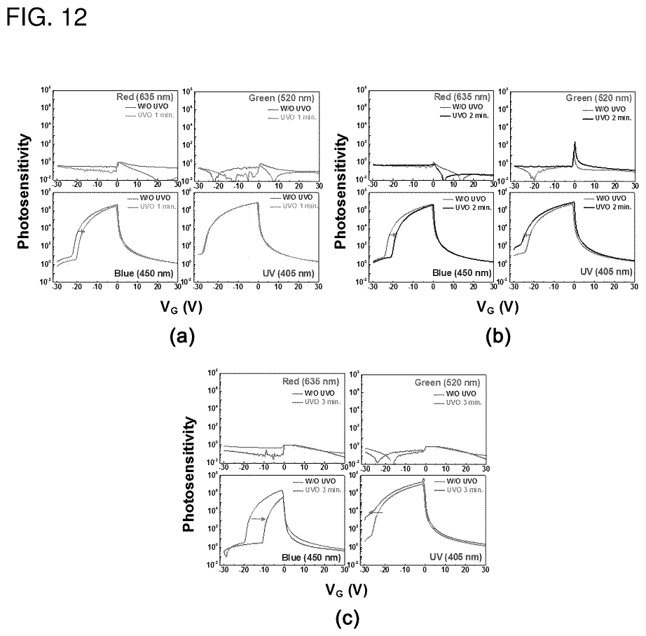

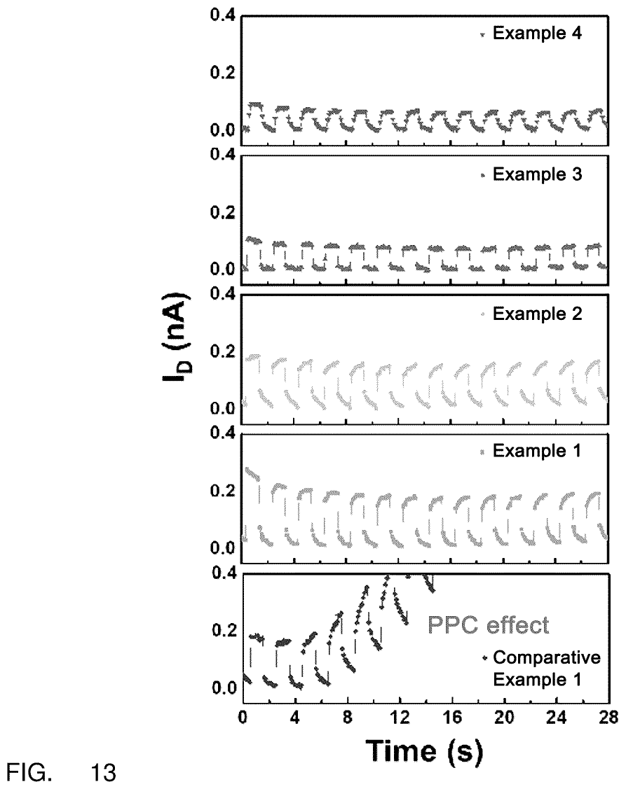

FIG. 12 is a graph showing photosensitivity according to wavelengths of a UV phototransistor manufactured according to an example of the present invention. More specifically, (a) of FIG. 12 shows photosensitivity according to wavelength of the UV phototransistor manufactured according to Example 5; (b) of FIG. 12 shows photosensitivity according to the wavelength of the UV phototransistor manufactured according to Example 6; and (c) of FIG. 12 shows photosensitivity according to wavelength of the UV phototransistor manufactured according to Example 7. Each of the UV phototransistors is graphed and compared with the photosensitivity of the UV phototransistor manufactured according to Example 1. Referring to FIG. 12, it can be seen that the UV phototransistors manufactured according to Examples 5 to 7 show a decreased response to visible light, specifically blue light (450 nm), while the response to UV light (405 nm) is enhanced compared to the UV phototransistor manufactured according to Example 1. In addition, the UV phototransistors manufactured according to Examples 5 to 7 show that as the UVO treatment time increases, the responsivity to blue light decreases further, while the responsivity to UV light improves significantly. In other words, the UV phototransistor of the present invention, by suppressing the response to blue light, which is closer to the UV range, can show a high response selectivity to UV light, thereby enhancing the performance as a UV sensor.

FIG. 13 is a graph illustrating the variation in current of a UV phototransistor manufactured according to an example of the present invention, depending on the application of light. In oxide semiconductors, the persistent photoconductivity (PPC) characteristic arises, wherein the increased conductivity after light irradiation is maintained for a prolonged period. Specifically, in optical sensors, the PPC characteristic must be suppressed to clearly distinguish the on-state (Id>0) and off-state (Id=0) of the current depending on whether light is applied, thereby ensuring superior performance as an optical sensor. Referring to FIG. 13, in the case of the UV phototransistor manufactured according to Comparative Example 1, the current value continuously increases due to the aforementioned PPC effect, and it is observed that the conductivity persists even when the light application is stopped, causing the current value to continue increasing. In contrast, the UV phototransistors manufactured according to Examples 1 to 4 clearly show a current value of 0 when the light application is stopped, and exhibit a current value greater than 0 when light application resumes. Thus, the UV phototransistor of the present invention effectively suppresses the PPC effect, enabling rapid response to UV light.

In addition, in an optical sensor (or UV sensor) such as the present invention, the larger the difference in current value (ΔI_{D}) depending on whether light is applied, the better the performance of the optical sensor can be considered.

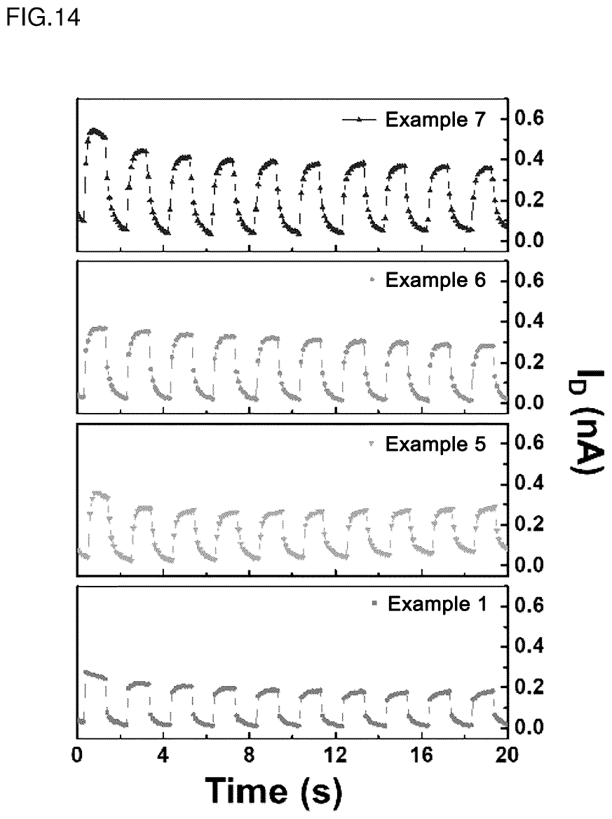

FIG. 14 is a graph illustrating the variation in current of the UV phototransistor manufactured according to an example of the present invention, depending on the application of light. Referring to FIG. 14, it can be observed that as the duration of the UVO treatment increases, the ΔID value increases from approximately 0.2 nA to approximately 0.6 nA. This indicates that the UV phototransistor of the present invention may be manufactured with superior performance through the implementation of UVO treatment.

The UV phototransistor according to the present invention may exhibit reduced responsivity in the visible light region and increased responsivity in the UV region.

Furthermore, the method of manufacturing a UV phototransistor according to the present invention enables the production of a UV phototransistor that reacts exclusively to light in the UV region through a simple process of altering the composition of the solvent.

The above description is merely illustrative of the technical concept of the present invention. It is understood that those skilled in the art to which the present invention pertains can make various modifications and alterations without departing from the essential characteristics of the present invention.

Therefore, the embodiments disclosed in the present invention are provided to explain rather than to limit the technical concept of the present invention, and the scope of the technical concept of the present invention should not be construed as being limited by these embodiments. The scope of protection for the present invention should be interpreted based on the claims below, and all technical concepts that fall within equivalent scopes should be construed as being included within the scope of the present invention.

### DESCRIPTION OF THE SYMBOLS

110: substrate
120: photoactive layer
131, 132: source electrode or drain electrode

What is claimed is:

1. A method of manufacturing an ultraviolet (UV) phototransistor, comprising:
mixing a solvent comprising 2-methoxyethanol, 2-ethoxyethanol, and ethylene glycol with an oxide semiconductor to prepare a photoactive solution;
applying the prepared photoactive solution onto a substrate to form a photoactive layer; and
forming electrodes spaced apart on the photoactive layer.

2. The method of claim 1,
wherein the oxide semiconductor is one or more materials selected from a group of ZnO, In₂O₃ and Indium-Gallium-Zinc-Oxide (IGZO).

3. The method of claim 1,
wherein the solvent comprises 2-methoxyethanol, 2-ethoxyethanol, and ethylene glycol in a volume ratio of 8:1:1 to 8:1:8.

4. The method of claim 1, further comprising:
performing UV/ozone (UVO) treatment on the formed photoactive layer.

5. The method of claim 4,
wherein the UVO treatment is performed for 1 to 10 minutes.

6. An ultraviolet (UV) phototransistor, comprising;
a substrate;
a photoactive layer formed by applying a photoactive solution onto the substrate, the photoactive solution prepared by mixing a solvent comprising 2-methoxyethanol, 2-ethoxyethanol, and ethylene glycol with an oxide semiconductor; and
electrodes formed spaced apart on the photoactive layer.

7. The UV phototransistor of claim 6,
wherein a thickness of the photoactive layer is 2 to 30 nm.

8. The UV phototransistor of claim 6,
wherein, in the UV phototransistor, photocurrent is generated through desorption of hydroxyl groups present on a surface of the photoactive layer.

9. The UV phototransistor of claim 8,
wherein the hydroxyl groups present on the surface of the photoactive layer are included at a ratio of 30 to 60% with respect to the surface of the photoactive layer.

10. The UV phototransistor of claim 6,
wherein, in the UV phototransistor, light absorption in visible region is reduced.
